(19) United States
(12) Patent Application Publication
(10) Pub. No.: US 2021/0273124 A1
(43) Pub. Date: Sep. 2, 2021

(54) DUAL-DEPTH VIA DEVICE AND PROCESS FOR LARGE BACK CONTACT SOLAR CELLS

(71) Applicant: Array Photonics, Inc., Tempe, AZ (US)

(72) Inventor: Lan ZHANG, Palo Alto, CA (US)

(21) Appl. No.: 17/260,208

(22) PCT Filed: Jul. 11, 2019
(86) PCT No.: PCT/US2019/041430

§ 371 Date: Jan. 13, 2021

Related U.S. Application Data
(60) Provisional application No. 62/697,797, filed on Jul. 13, 2018.

(51) Int. Cl. H01L 31/0443; H01L 31/02; H01L 31/048; H01L 31/0725

(52) U.S. Cl. CPC H01L 31/0443; H01L 31/0725; H01L 31/048; H01L 31/02008

(57) ABSTRACT

Dual-depth through-wafer-via semiconductor devices and methods for fabricating dual-depth through-wafer-via semiconductor devices are disclosed. In particular, back-contact-only multijunction photovoltaic cells and the process flows for making such cells are disclosed. The dual-depth through-wafer-via multijunction photovoltaic cells include through-wafer-vias for interconnecting the front surface epitaxial layer to a contact pad on the back surface. Before etching the through-wafer-vias the substrate is thinned to less than 150 pm. The dual-depth through-wafer-vias are formed using a two-step wet etch process that removes semiconductor materials non-selectively without major differences in etch rates between heteroepitaxial III-V semiconductor layers. Low-stress passivation layers are used to reduce the thermo-mechanical stress of the semiconductor devices. A bypass diode is integrated in the recess on the backside formed by the dual-depth through-wafer structure.

### FIELD

This disclosure relates to photovoltaic cells, methods for fabricating photovoltaic cells, methods for assembling solar panels, and solar panels comprising photovoltaic cells. Particularly, the disclosure relates to multijunction photovoltaic cells with through-wafer-vias and a discrete bypass diode integrated onto the backside. The multijunction photovoltaic cells include dual-depth through-wafer-vias for interconnecting a front surface epitaxial layer to a contact pad on the back surface, and for providing a recess on the back side that allows mounting of a bypass diode. The dual-depth through-wafer-vias are formed using a two-step wet etch process that removes a portion of the substrate and then removes semiconductor materials non-selectively without major differences in etch rates between heteroepitaxial III-V semiconductor layers. Low-stress passivation layers are used to improve reliability of the devices over a broad temperature range. Elimination of a contact on the front side of the wafer allows single side welding or wire bonding.

### BACKGROUND

Multijunction photovoltaic cells are used in terrestrial and space solar conversion applications because of their high efficiencies. Such cells have multiple junctions, or sub-cells, that form diodes and are connected in series. The structures are realized through epitaxial growth of multiple layers on semiconductor substrates. Each subcell in a stack possesses a unique bandgap and is optimized for absorbing a different portion of the solar spectrum, thereby improving efficiency of solar energy conversion. These subcells are chosen from a variety of semiconductor materials with different optical, electrical, and physical properties in order to absorb different portions of the solar spectrum. The materials are arranged such that the bandgap of the subcells is progressively smaller from the top subcell (closest to the front surface, from which the cell receives light) to the bottom subcell (furthest from the front surface). Thus, high-energy photons are absorbed in the top subcell and less energetic photons pass through to the lower subcells where they are absorbed. In every subcell, electron-hole pairs are generated and current is collected at ohmic contacts in the solar cell. Semiconductor materials used to form the subcells include, for example, germanium and alloys of one or more elements from group III and group V on the periodic table. Examples of these alloys include, for example, indium gallium phosphide, indium phosphide, gallium arsenide, aluminum gallium arsenide, indium gallium arsenide, and dilute nitride compounds. For ternary and quaternary compound semiconductors, a wide range of alloy ratios can be used. Examples of multijunction solar cells using multiple heteroepitaxial layers are described in U.S. Pat. Nos. 8,575,473, 8,697,481 and 9,214,580.

Using conventional photovoltaic cells, solar arrays used to power space satellites are typically assembled manually which results in high cost and introduces the risk of reliability issues. Nearly all currently available space photovoltaic cells employ welded interconnect tabs for adjacent cells, and a welded or monolithically integrated bypass diode on each individual photovoltaic cell. Photovoltaic cells assembled with bypass diodes, interconnects, and coverglass are referred to in the aerospace industry as “Coverglass Interconnected Cells” or “CICs”. These CICs are typically assembled using manual process steps. The mechanical design of commercially available CICs has not changed substantially in the past two decades. With electrical contacts on the front side and the back side of the wafer, welding is required to interconnect devices on both sides of the solar cell.

To reduce the number of overall steps associated with the expensive, manual interconnection process steps used in both CIC and solar array assembly, the industry has been moving to increasingly larger CICs using both 4-inch and 6-inch Ge substrates.

Normally, a photovoltaic cell contributes around 20% to the total cost of a photovoltaic power module. Higher photovoltaic cell efficiency means more cost-effective modules. Fewer photovoltaic devices are then needed to generate the same amount of output power, and the generation of higher power with fewer devices leads to reduced system costs, such as costs associated with structural hardware, assembly processes, wiring for electrical connections, etc. In addition, by using high efficiency photovoltaic cells to generate the same power, less surface area, fewer support structures, and lower labor costs are required for assembly installation.

Photovoltaic modules are a significant component in spacecraft power systems. Lighter weight and smaller photovoltaic modules are always preferred because the lifting cost to launch satellites into orbit is very expensive. Efficient surface area utilization of photovoltaic cells is especially important for space power applications to reduce the mass and fuel penalty associated with large photovoltaic arrays. Higher specific power (watts generated over photovoltaic array mass), which reflects the power one solar array can generate for a given launch mass, can be achieved with more efficient photovoltaic cells because the size and weight of the photovoltaic array will be less for the same power output. Additionally, higher specific power can be achieved using smaller cells that are more densely arranged over a photovoltaic array of a given size and shape.

Interconnection of multijunction photovoltaic cells is typically accomplished by welding interconnect ribbons to front side and back side contacts on the p- and n-sides of the device. Interconnecting multijunction photovoltaic cells using these methods can be costly. To minimize interconnection costs, it can be desirable to use larger area photovoltaic cells to reduce the number of interconnects that need to be formed for a given panel area. This can lead to a reduction in surface area utilization. Interconnect welding is usually the most delicate operation in CIC assembly. In the CIC process, photovoltaic cells must be mounted on a support and interconnected using a substantial amount of manual labor. For example, first individual CICs are produced with each front-side interconnect individually welded to each cell, and each cover glass is individually mounted. Then, these CICs are interconnected in series to form strings, generally in a substantially manual manner, including welding or soldering steps on the back-side of the cells. Then, these strings are applied to a panel or substrate and interconnected in a process that includes the application of adhesive, wiring, and other assembly steps. During the welding process steps, cells can break or later crack after mounting in a module due to damage incurred during the process.

More recently, solar cells employing via structures have been proposed to facilitate electrical connections on one side of the wafer. Conventional solar cell designs require metallization to form top-surface electrodes, which are usually regular grids of metal fingers or wires. These structures result in shadowing loss, since the metal gridlines prevent light from being absorbed under them. This can reduce the active area of the solar cells. Through wafer-vias (TWVs) are electrical interconnects between the top (front) and bottom (back) surfaces of a device. TWVs are widely used in microelectronics applications and have been proposed for solar cells to reduce shadowing losses as well as to facilitate subsequent packaging. An example of this approach is known as the surface mount coverglass cell (SMCC). Examples of SMCC devices, and associated processing of TWVs are described in U.S. Pat. No. 9,680,035, and U.S. Application Publication No. 2017/0213922, each of which is incorporated by reference in their entirety. SMCCs are photovoltaic cells with TWVs, all-backside surface mount contacts and coverglass integrated at the wafer-level. However, this process is suited to smaller area cells, less than about 2 cm square, with thin substrates, and requires surface mount technologies that presently have not been tested to establish long term reliability. Furthermore, for large area applications, the coefficient of thermal expansion (CTE) should be matched to the CTE of the printed circuit board (PCB) to which the cell is mounted. Large area PCBs with sufficiently low CTEs are either not available or are expensive.

There is therefore a need to provide a simpler process flow for the integration and welding steps required to produce panels formed by multiple interlinked photovoltaic cells. With all the electrical contacts on the backside of the photovoltaic cell, it becomes possible to simplify the connection process by eliminating the front-side welding step. Furthermore, it is also possible to integrate a bypass diode in the substrate, allowing industry-standard welding processes on one side of the device only.

Multijunction solar cell structures and devices that can be interconnected using a single side welding process, compatible with standard solar lay-down processing, are required.

### SUMMARY

According to the present invention, dual-depth through-wafer-via structures comprise: a substrate having a front substrate surface and a back substrate surface, wherein the substrate has a thickness from 20 μm to 200 μm; a plurality of heteroepitaxial layers overlying the front substrate surface; a front surface contact overlying a portion of and electrically connected to the plurality of heteroepitaxial layers; an optical adhesive overlying the front surface contact and the plurality of heteroepitaxial layers; a coverglass overlying the optical adhesive; a back surface contact pad underlying a portion of and electrically connected to the back substrate surface; a front surface contact pad underlying and insulated from the back substrate surface; and a dual-depth through-wafer-via interconnecting the front surface contact pad and the front surface contact, wherein the dual-depth through-wafer-via comprises: a sidewall and a low-stress passivation layer lining the sidewall; and a through-wafer-via metal overlying the passivation layer.

According to the present invention, semiconductor devices comprise a dual-depth through-wafer-via structure according to the present invention.

According to the present invention, multijunction photovoltaic cells comprise a dual-depth through-wafer-via structure according to the present invention.

According to the present invention, photovoltaic modules comprise a plurality of multijunction photovoltaic cells according to the present invention.

According to the present invention, methods of fabricating a through-wafer-via structure, comprise:

(a) providing a semiconductor wafer, wherein the semiconductor wafer comprises: a substrate comprising a front substrate surface and a back substrate surface; a plurality of heteroepitaxial layers overlying the front substrate surface; a front surface contact overlying and electrically connected to a portion of the plurality of heteroepitaxial layers; an optical adhesive overlying the front surface contact and the plurality of heteroepitaxial layers; and a coverglass overlying the optical adhesive layer;

(b) forming a broad area via structure within the back substrate surface;

(c) forming a through-wafer-via within the broad area via structure and interconnecting the front surface contact, wherein the through-wafer-via comprises a sidewall and a low-stress passivation layer lining the sidewall, and a through-wafer-via metal overlying the passivation layer; and

(d) forming a front contact pad interconnecting the through-wafer-via and the front surface contact.

According to the present invention, semiconductor devices comprise a dual-depth through-wafer-via structure fabricated by a method according to the present invention.

According to the present invention, multijunction photovoltaic cells comprise a dual-depth through-wafer-via structure fabricated by a method according to the present invention.

According to the present invention, photovoltaic modules comprise a plurality of multijunction photovoltaic cells according to the present invention.

### BRIEF DESCRIPTION OF THE DRAWINGS

The drawings described herein are for illustration purposes only. The drawings are not intended to limit the scope of the present disclosure.

FIG. 1 shows a cross-sectional of an example of a multijunction photovoltaic cell.

FIGS. 2-13B illustrate an example of a process flow for fabricating a multijunction photovoltaic cell having a dual-depth via structure with TWVs and an integrated bypass diode according to the present disclosure.

FIG. 14 shows a cross-sectional view of a multijunction photovoltaic cell with a dual-depth TWV and integrated bypass diode fabricated using the method illustrated in FIGS. 2-13B.

FIG. 15 shows a cross-sectional view of a multijunction photovoltaic cell with a dual-depth TWV and integrated bypass diode fabricated using the method illustrated in FIGS. 2-13B.

FIG. 16 shows a cross-sectional view of a multijunction photovoltaic cell with a dual-depth TWV and integrated bypass diode fabricated using the method illustrated in FIGS. 2-13B.

FIGS. 17A and 17B show a front-side view and a backside view, respectively, of a solar cell according to FIG. 15.

FIG. 17C shows a backside view of another solar cell according to FIG. 15.

FIGS. 18A and 18B show back-side views of solar cells according to FIG. 14.

FIG. 19 shows a back-side view of a solar cell according to FIG. 16.

FIG. 20 shows a back-side view of two interconnected solar cells according to FIG. 16.

### DETAILED DESCRIPTION

The following detailed description refers to the accompanying drawings that show, by way of illustration, specific details and embodiments in which the invention may be practiced. These embodiments are described in sufficient detail to enable those skilled in the art to practice the present invention. Other embodiments may be utilized and structural, logical, and electrical changes may be made without departing from the scope of the invention. The various embodiments disclosed herein are not necessarily mutually exclusive, as some disclosed embodiments may be combined with one or more other disclosed embodiments to form new embodiments. The following detailed description is, therefore, not to be taken in a limiting sense, and the scope of the embodiments of the present invention is defined only by the appended claims, along with the full scope of equivalents to which such claims are entitled.

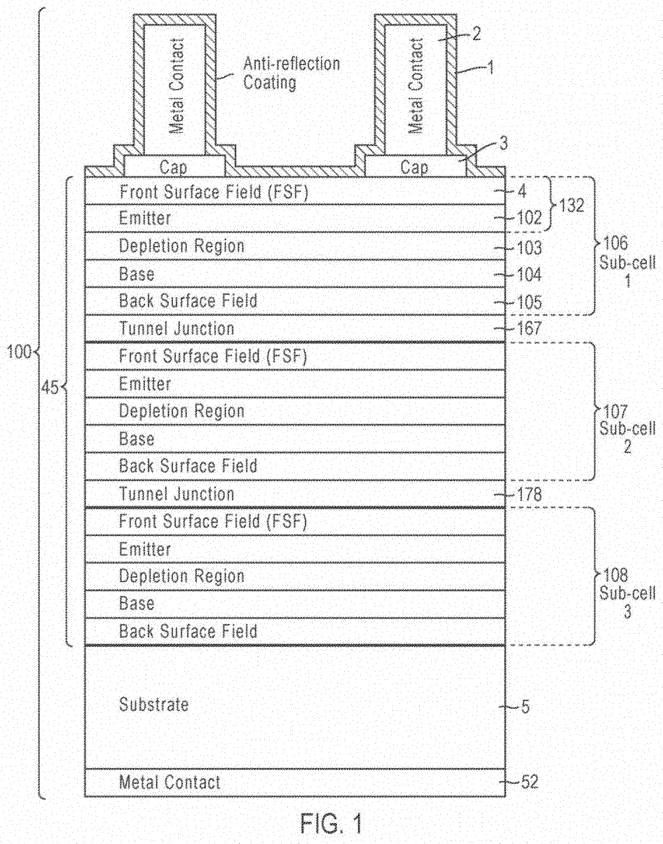

Conventional multijunction solar cells have been widely used for terrestrial and space applications because of their high conversion efficiency. Multijunction solar cells (100), as shown in FIG. 1, include multiple diodes in series connection, known in the art as junctions or subcells (106, 107, and 108), realized by growing thin regions of epitaxy in a stack on a semiconductor substrate. Each subcell in a stack possesses a unique bandgap and is optimized for absorbing a different portion of the solar spectrum, thereby improving efficiency of solar energy conversion. These subcells are chosen from a variety of semiconductor materials with different optical and electrical properties that absorb different portions of the solar spectrum. The materials are arranged such that the bandgap of the subcells becomes progressively narrower from the top subcell (106) to the bottom subcell (108). Thus, high-energy photons are absorbed in the top subcell and less energetic photons pass through to the lower subcells where they are absorbed. In every subcell, electron-hole pairs are generated and current is collected at ohmic contacts in the solar cell. Semiconductor materials used to form the subcells include, for example, germanium and alloys of one or more elements from group III and group V on the periodic table. Examples of these alloys include, for example, indium gallium phosphide, indium phosphide, gallium arsenide, aluminum gallium arsenide, indium gallium arsenide, and dilute nitride compounds. For ternary, quaternary, and quinary compound semiconductors, a wide range of alloy ratios can be used.

As shown in FIG. 1, a multijunction solar cell 100 can include a substrate 5, a back metal contact 52 underlying and electrically connected to the substrate 5, a subcell 108 overlying the substrate, a subcell 107 overlying the subcell 108, and a subcell 106 overlying the subcell 107. A cap region 3 overlies and is electrically connected to a portion of subcell 106 and a metal contact 2 overlies and is electrically connected to each of the cap regions 3. An antireflection coating 1 overlies a portion of subcell 106, cap regions 3, and metal contacts 2. Heteroepitaxial region 45 includes subcells 106, 107, and 108, and each subcell is interconnected to the adjacent subcell by a tunnel junction 167 or 178. Each subcell includes multiple heteroepitaxial layers. For example, subcell 106 includes front surface field 4, emitter 102, depletion region 103, base 104, and back surface field 105. Front surface field 4 and emitter 102 form element 132. Electrical connection with the device can be made to backside metal contact 52 and to frontside surface contacts 2, via a welding process.

A bypass diode (not shown) may be integrated on the front surface or on the back surface of a device. While a recess may be provided, for example as described in U.S. Pat. No. 5,616,185 or U.S. Pat. No. 6,103,970, integration of multiple cells via strings into panels requires a front-side welding process and a backside welding process, as well as coverglass integration at the cell level after the front-side welding step is performed.

The fabrication of single-side contacted multijunction photovoltaic cells includes forming high quality dual-depth through-wafer-vias (TWVs) across the complex heteroepitaxial structure.

When referring to the various surfaces of a multijunction solar cell, the front surface or top surface refers to the surface designed to face incident solar radiation, and the back surface or bottom surface refers to the side of the solar cell facing away from the incident solar radiation.

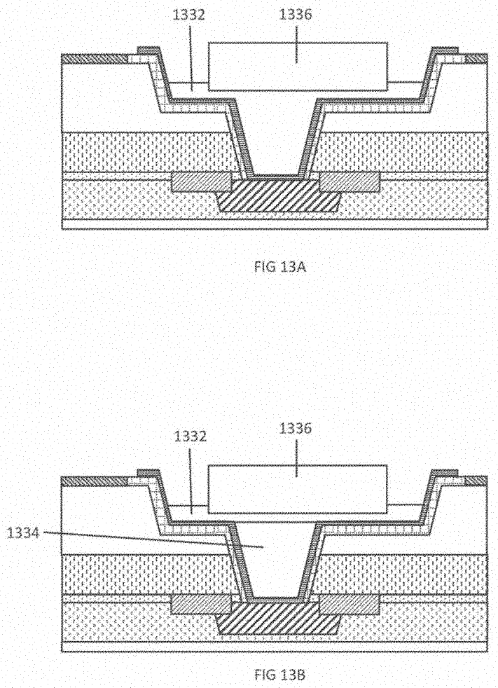

The coverglass 1208 (FIG. 12) can be any suitable optically transparent dielectric material appropriate for use in solar cells. The coverglass can be a sheet of material. The coverglass can be any suitable thickness for protecting the solar cell from the environment and radiation. For example, the coverglass can be from 20 μm to 600 μm thick, from 40 μm to 500 μm thick, from 50 μm to 400 μm thick, or from 75 μm to 300 μm thick.

The optical adhesive 1207 (FIG. 12) can be any suitable optical adhesive capable of bonding the coverglass to underlying layers including to a heteroepitaxial layer, to an antireflection coating (ARC), and/or to metal contact layers. An example of a suitable optical adhesive is Dow Corning® 93-500 space grade encapsulant. An optical adhesive can be, for example, from 2 μm to 200 μm thick, from 5 μm to 150 μm thick, or from 10 μm to 100 μm thick.

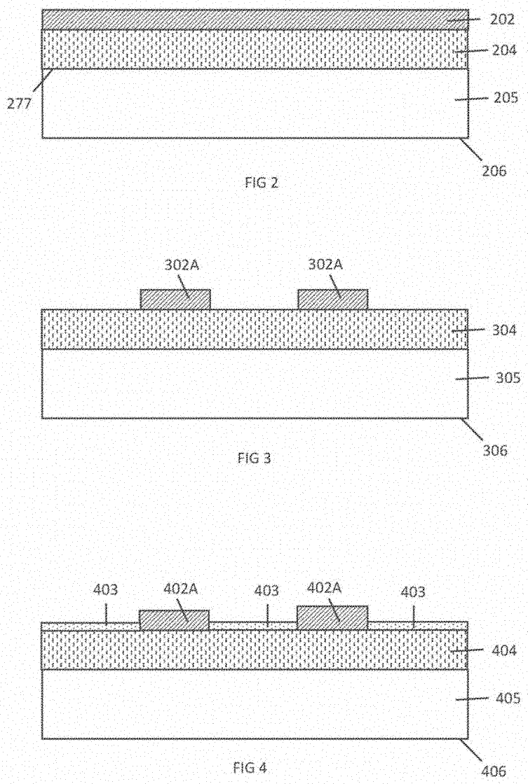

FIGS. 2 to 13 illustrate an example of process steps used to fabricate a dual-depth via cell provided by the present disclosure. FIGS. 2 to 6 show steps associated with front-side processing. FIGS. 7 to 13B show steps associated with back-side processing including deposition of a low-stress passivation layer, forming a dual-depth via structure and integrating a backside bypass diode provided by the present disclosure. The process steps and final product described can be modified by one skilled in the art to accommodate a wide variety of semiconductor devices; the steps and final product are not limited to solar cells and are applicable to other semiconductor devices and in particular to minority carrier devices.

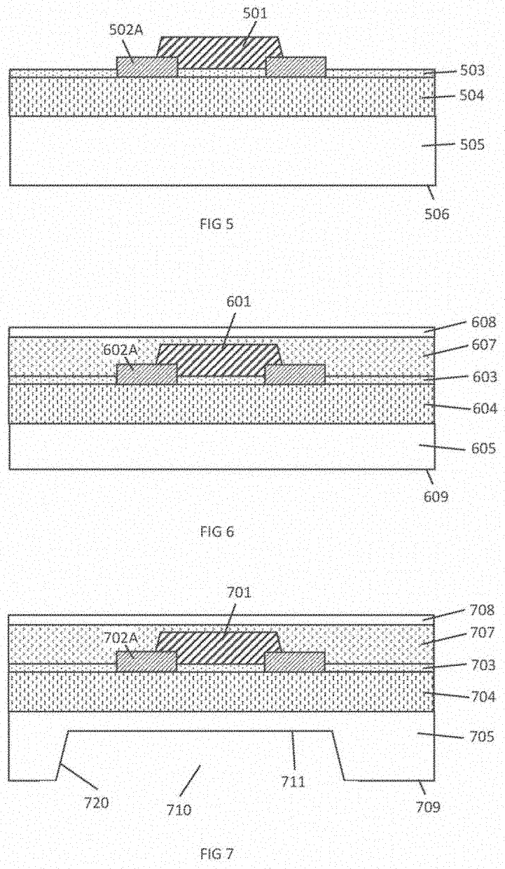

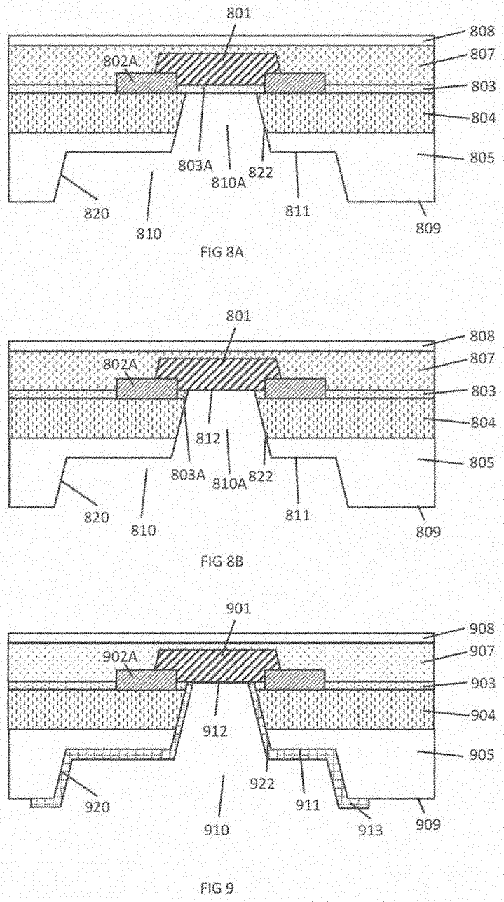

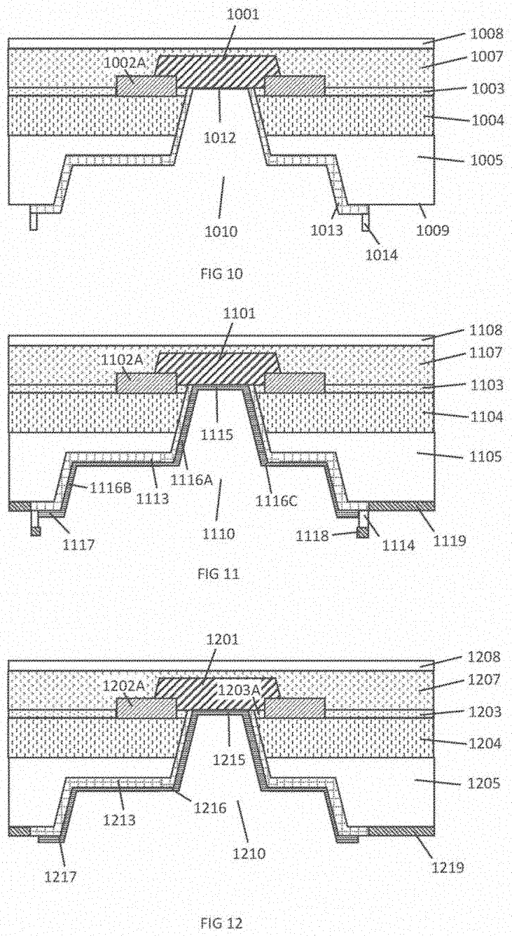

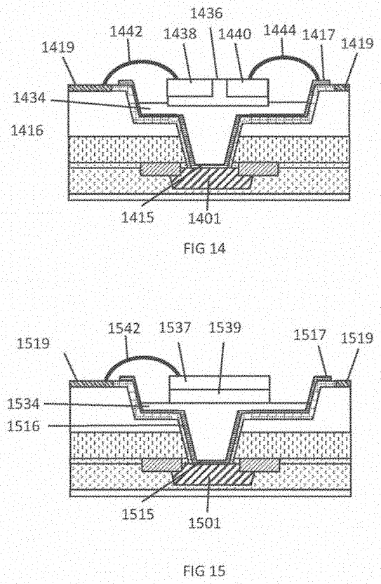

The semiconductor wafer cross-sections shown in FIGS. 2 to 13B can be summarized as follows: FIG. 2 shows a heteroepitaxial layer on an unmodified substrate; FIG. 3 shows a wafer after contact cap layer patterning; FIG. 4 shows a wafer following application of an antireflection coating (ARC); FIG. 5 shows a wafer following application of a front-side metal pad; FIG. 6 shows a wafer after wafer bonding (coverglass integration), and optional back-grinding, and wet etch back-thinning; FIG. 7 shows a wafer after broad via lithography and timed wet etch; FIG. 8A shows a wafer after via etch stop to the ARC/dielectric layer; FIG. 8B shows a wafer after via etch stop (ARC/dielectric) removal; FIG. 9 shows a wafer after passivation layer patterning and hard bake; FIG. 10 shows a wafer after back-side and via-metal isolation lithography; FIG. 11 shows a wafer after back side and TWV-metal deposition; FIG. 12 shows a device after metal lift-off (TWV metal and back-side metal separation); FIGS. 13A-13B show integration of a bypass diode; and FIG. 14 shows a completed device after bypass diode integration.

A semiconductor wafer can first undergo front-side processing (FIGS. 2 to 6). As shown in FIG. 2, a semiconductor wafer can comprise a substrate 205 having a back surface 206 and a front surface 277. A heteroepitaxial layer 204 overlies the front surface 207 of substrate 205. Materials used to form the substrate include, for example, germanium, gallium arsenide, alloys of germanium, and alloys of gallium arsenide. For simplicity, heteroepitaxial layer 204 is shown as a single layer. However, in a multijunction solar cell, it will be understood that multiple epitaxial layers are grown overlying each other, to form a multi-layered heteroepitaxial stack, as illustrated, for example, in FIG. 1. Materials used to form the heteroepitaxial layer include, for example, alloys of one or more elements from group III and group V on the periodic table, such as indium gallium phosphide, indium phosphide, gallium arsenide, aluminum gallium arsenide, indium gallium arsenide, and dilute nitride compounds.

Heteroepitaxial layer 204 can comprise multiple heteroepitaxial layers which are deposited or grown on a substrate. Heteroepitaxial layer 204 comprises an active multijunction photovoltaic cell. The multijunction photovoltaic cell can comprise one or more subcells. Examples of multijunction photovoltaic cells are disclosed in U.S. Pat. Nos. 8,912,433, 8,962,993, 9,214,580, in U.S. Application Publication No. 2017/0110613, and in U.S. Publication No. 2017/0365732, each of which is incorporated by reference in its entirety. The heteroepitaxial layer can include multiple layers of semiconductor material used to fabricate a multijunction photovoltaic cell such as shown in FIG. 1. In certain multijunction photovoltaic cells, at least one of the junctions can comprise a dilute nitride material such as GaInNAsSb, GaInNAsBi, or GaInNAsSbBi. Each of the subcells can be lattice matched to each of the other subcells forming the multijunction photovoltaic cell and can be lattice matched to the substrate.

“Lattice matched” refers to semiconductor layers for which the in-plane lattice constants of adjoining materials in their fully relaxed states differ by less than 0.6% when the materials are present in thicknesses greater than 100 nm. Further, subcells that are substantially lattice matched to each other means that all materials in the subcells that are present in thicknesses greater than 100 nm have in-plane lattice constants in their fully relaxed states that differ by less than 0.6%. In an alternative meaning, substantially lattice matched refers to the strain. As such, base layers can have a strain from 0.1% to 6%, from 0.1% to 5%, from 0.1% to 4%, from 0.1% to 3%, from 0.1% to 2%, or from 0.1% to 1%; or can have strain less than 6%, less than 5%, less than 4%, less than 3%, less than 2%, or less than 1%. Strain refers to compressive strain and/or to tensile strain.

A substrate 205 included in the semiconductor layer can be active and can form one of the active junctions of the photovoltaic cell, or the substrate can be inactive. An example of an active substrate is Ge. A Ge substrate can be, for example, less than 200 μm thick, less than 175 μm thick, less than 150 μm thick, or less than 100 μm thick. A Ge substrate can be, for example, from 75 μm to 200 μm thick, from 75 μm to 175 μm thick, from 75 μm to 150 μm thick, from 75 μm to 175 μm thick, or from 75 μm to 150 μm. An example of an inactive substrate is GaAs, which can be, for example, from 75 μm to 400 μm thick, from 75 μm to 200 μm thick, from 75 μm to 150 μm thick, or from 75 μm to 100 μm thick.

FIGS. 2 and 3 show cap layer 202 and patterned cap regions 302A that are formed on the front-side of the semiconductor wafer, overlying the heteroepitaxial layer (204 and 304). The cap regions 302A are highly doped semiconductor layers that facilitate electrical interconnection to the multijunction solar cell. Cap layer 202 is patterned using lithography, to form patterned cap regions 302A. These may be patterned in a disk shape but can also be patterned in any suitable shape and in any suitable geometric configuration, such as shaped in the form of gridlines, busbars, pads and/or any type of conductive element of an electrical device. FIG. 3 shows substrate 305, back substrate surface 306, heteroepitaxial layer 304, and patterned cap regions 302A following post-cap etch.

An anti-reflection coating (ARC) (403 in FIG. 4) may be applied over the heteroepitaxial layer 404 and between patterned cap regions 402A. FIG. 4 shows substrate 405, back substrate surface 406, heteroepitaxial layer 404, ARC 403, and patterned cap regions 402A following post-cap etch and deposition of ARC 403 over the portion of the heteroepitaxial layer 404 not covered by patterned cap regions 402A.

A front surface contact (501 in FIG. 5) and narrow metal gridlines (not shown) can be electrically interconnected to the patterned cap regions 502A. At the end of front-side processing, a semiconductor wafer with an unmodified substrate layer (506) can be obtained, as shown in FIG. 5. FIG. 5 shows substrate 505, back substrate surface 506, heteroepitaxial layer 504 overlying substrate 505, ARC 503 overlying a portion of heteroepitaxial layer 504, patterned cap regions 502A, and front surface contact 501 electrically interconnected to patterned cap regions 502A.

As shown in FIG. 6, the semiconductor wafer shown in FIG. 5 can be bonded to a cover glass 608 with an optically clear adhesive 607. The cover glass 608 can be any suitable optically transparent dielectric material appropriate for use in solar cells. The coverglass can be a sheet of material. Cover glass 608 may be a space grade cover glass, which may be made, for example, of borosilicate glass. The coverglass can be any suitable thickness for protecting the solar cell from the environment and radiation. For example, the coverglass can be from 20 μm to 600 μm thick, from 40 μm to 500 μm thick, from 50 μm to 400 μm thick, or from 75 μm to 300 μm thick. The optical adhesive 607 can be any suitable optical adhesive capable of bonding the coverglass to underlying layers including to a heteroepitaxial layer, to an antireflection coating (ARC), and/or to metal contact layers. An example of a suitable optical adhesive is Dow Corning® 93-500 space grade encapsulant. An optical adhesive can be, for example, from 2 μm to 200 μm thick, from 5 μm to 150 μm thick, or from 10 μm to 100 μm thick.

The back side of the substrate (506 in FIG. 5) can be optionally thinned (609 in FIG. 6) by wet etching, back-grinding, or other methods. A thinned substrate 605 can be between 25 μm and 200 μm, such as from 25 μm to 150 μm, or from 25 μm to 100 μm, thick post-thinning. Thinned substrates are desirable in some applications, for example, in space solar cells. Thinned substrates are also useful with respect to the subsequent processing to form through-wafer-vias. Problems associated with processing thicker substrates can affect geometry and resolution of the vias. Not only are longer etch times required, but there can be issues delivering etchants to the etch front, affecting the rate of etching. The uniformity of the etch at the surface may result in incomplete removal of specific layers. Etched material may be redeposited and undercutting of layers may also occur. This can affect the surface roughness of the etched via. These effects can lead to additional subsequent processing problems, which in turn can lead to points of failure in the fabricated devices. FIG. 6 shows thinned substrate 605, back substrate surface 609, heteroepitaxial layer 604, ARC 603 overlying portions of the heteroepitaxial layer 604, patterned cap regions (post-cap etch) 602A overlying portions of the heteroepitaxial layer 604, front surface contact 601 overlying a portion of the ARC 603 between the patterned cap regions 602A and electrically connected to patterned cap regions 602A, optically clear adhesive 607, and cover glass 608.

In FIG. 7, the back substrate surface 709 of substrate 705 is patterned with a photosensitive polymer or any suitable masking material (not shown) in at least one desired broad area via 710. At least one broad area via 710, as shown, overlaps spatially with front surface contact 701 and patterned cap regions 702A. A second broad area via does not need to align with a front surface contact. Patterned cap regions 702A can be in the shape of an annular ring that forms a perimeter around the ARC-adjacent region of the TWV to be formed in the next process step. Etching broad area vias 710 starts from the back substrate surface 709 and proceeds through substrate 705, stopping at a surface 711 within the substrate 705, producing a via with sidewalls 720. An etchant mixture for etching the broad area via can comprise a mixture of citric acid, hydrogen peroxide and water, with a volumetric ration of 1:1:4. The etchant mixture can have a temperature that ranges from about 10° C. to 60° C.

Other suitable wet etching methods and dry etching methods are also known and may be used. For example, peroxide-based etchants are disclosed by Ehman et al., in “The Influence of the Complexing Agent Concentration on the Etch Rate of Germanium”, J. Electrochem. Soc., Vol. 118, Iss. 9, pp. 1443-1447, 1971. Etching of Ge in acids, bases and peroxide-based mixtures is also reported by Sioncke et al., in “Etch rates of Ge, GaAs and InGaAs in acids, bases and peroxide based mixtures”, ECS Transactions, 16(10), pp. 451-460, 2008. Wet etchant mixtures comprising hydrochloric acid and iodic acid are disclosed, for example, in U.S. Pat. No. 9,263,611. A comprehensive list of wet etchants, etch rates, and selectivity relationships was published by Clawson, Materials Science and Engineering, 31 (2001) 1-438.

Dry etching, involving the removal of semiconductor material by exposing the material to a plasma of reactive gases in a vacuum chamber may also be used.

Etching stops after a predetermined etch time at surface 711, the depth of the etch determined by the etching rate and etching time. For example, using a 150 μm thick substrate, the depth of the via 710 can be up to about 150 μm, leaving the thickness of substrate 705 between 0 μm and about 30 μm at the bottom of the broad area via. Then, the patterned photosensitive polymer/masking material (not shown) is removed. FIG. 7 also shows heteroepitaxial layer 704, optically clear adhesive 707, cover glass 708, ARC layer 703, patterned cap regions 702A, and front surface contact 701.

In FIG. 8A, the back substrate surfaces 809 and 811 and sidewall 820 are patterned with a photosensitive polymer or any suitable masking material in a desired TWV, aligning the TWV with front surface contact 801 and patterned cap regions 802A. More than one TWV can be formed within broad area via 810, each aligning with a different front surface contact. Patterned cap regions 802A can be in the shape of an annular ring that forms a perimeter around the ARC-adjacent region of the TWV. Etching TWVs 810A starts from the back substrate surface 811 and proceeds through heteroepitaxial layer 804, and stops at the ARC layer 803A. An etchant mixture for etching the TWV can comprise a volumetric ratio of 10% to 50% hydrochloric acid with a volumetric ratio of 10% to 50% iodic acid in deionized water. The etchant mixture can have a temperature that ranges from 10° C. to 140° C. Etching stops at the ARC 803 that serves as a selective dielectric etch stop layer for the etching process. Referring to FIG. 8B, after the via etch and via formation shown in FIG. 8A, the ARC at the top of the TWV can subsequently be removed, for example by dry etching or by wet etching using, for example, hydrofluoric acid, to expose the bottom surface 812 of front surface contact 801. Residual ARC 803A can remain between the patterned cap regions 802A and the TWV 810A, which has a sidewall 822. Then, the patterned photosensitive polymer/masking material (not shown) is removed. TWV 810A and the broad area via (indicated as 710 in FIG. 7) form a dual-depth TWV.

FIGS. 8A and 8B also show heteroepitaxial layer 804, optically clear adhesive 807, cover glass 808, back substrate surface 809, thinned substrate 805, front surface contact 801, and sidewall 820 for the broad area via.

Suitable wet etchant mixtures comprising hydrochloric acid and iodic acid are disclosed, for example, in U.S. Pat. No. 9,263,611, which is incorporated by reference in its entirety. Smooth sidewalls etched with the etchant mixture can comprise traces of iodine. The heteroepitaxial sidewalls can be characterized by a macroscopically smooth surface without significant undercutting and that continuously widens from the substrate to the ARC. In some embodiments, the etchant mixture used can comprise a volumetric ratio of 30% to 35% hydrochloric acid with a volumetric ratio of 14% to 19% iodic acid in deionized water. The etchant mixture can have a temperature within the range from 30° C. to 45° C.

Other wet etching methods and dry etching methods are also known and may be used. A comprehensive list of wet etchants, etch rates, and selectivity relationships was published by Clawson, Materials Science and Engineering, 31 (2001) 1-438.

Dry etching, involving the removal of semiconductor material by exposing the material to a plasma of reactive gases in a vacuum chamber may also be used.

In certain embodiments, patterned cap regions may not be present, and the front surface contact may overly only the ARC 803. After wet etch and TWV formation, a portion or the entire ARC previously underlying the metal pad may be removed to expose the bottom surface 812 of the front surface contact 801. If a portion of the ARC layer is removed there will be a residual ARC 803A between a portion of the front surface contact 801 and the heteroepitaxial layer 804.

As shown in FIG. 9, a passivation layer 913 is applied over a portion of the thinned back substrate surface 909 according to a desired pattern to passivate the substrate 905 from electrical connection to the front surface contact 901. The passivation layer 913 also lines the sidewalls 920, 922, and surface 911 of the dual-depth TWV 910 and provides a conformal coating lining the TWV sidewalls 920 and 922, surface 911 and covering a portion of the back surface of substrate 905 adjacent the dual-depth TWV 910.

The bottom surface 912 of the front surface contact 901 remains exposed after TWV etch stop (ARC) removal and deposition of passivation layer 913. FIG. 9 shows front surface contact 901, patterned cap regions (post-cap etch) 902A, ARC 903, heteroepitaxial layer 904, substrate 905, optically clear adhesive 907, cover glass 908, thinned back substrate surface 909, dual-depth TWV 910, exposed bottom surface 912 of the front surface contact 901 after TWV etch stop (ARC) removal, and deposition of passivation layer 913.

In applications where operation over a broad temperature range is required, and where temperature cycling occurs, such as space solar applications, passivation layer 913 is chosen to minimize the thermo-mechanical stress in the device and is a low-stress passivation layer. This requirement is also useful in subsequent processing and packaging steps. Because the semiconductor structure is bonded to a cover glass 908 with an optically clear adhesive 907, the temperature ramps for processing and the maximum process temperature that can be used in fabricating the device is limited, which also affects the choice of suitable materials that may be deposited to form the device. To minimize the stress between the different layers making up the device, passivation layer 913 should have a coefficient of thermal expansion (CTE) close to that of the semiconductor layers (heteroepitaxial layer 904 and substrate 905) and should be deposited under processing conditions that the cover glass 908 and the optical adhesive 907 can withstand. The CTE for semiconductor materials is typically in the range from about 2.5 ppm/° C. to about 7 ppm/° C.

Common passivation materials used for microelectronics and semiconductors include photoimagable polymers, for example SU-8, AZ 15NXT, and PDMS. Non-photoimagable polymers for passivation are also known and used. These materials are used because they provide good adhesion to the underlying surface onto which they are deposited and can be deposited using spin coating over broad thickness ranges to produce a conformal coating. However, these passivation materials can have a high CTE, for example, on the order of several tens of ppm/° C. (typically >20 ppm/° C.). Consequently, the large CTE mismatch between a typical passivation material having a high CTE and the CTE of the semiconductor layers can cause a large thermal stress in any subsequent processing or packaging steps, or when a device operates over a large temperature range. Contraction and expansion of the passivation layer can introduce cracks into the semiconductor device.

Dielectric materials such as silicon nitride, silicon dioxide and titanium dioxide are often used as passivation layers. These materials have CTEs close to the CTE of the semiconductor layer. However, producing a conformal coating using these dielectric materials can be more difficult on structures such as TWVs, and in particular on the via sidewall and near the via edge. This can result in imperfect coverage, leading to shorts formed during subsequent metallization steps. Improved adhesion can be achieved using higher temperature deposition, for example, using a high temperature or high energy plasma deposition process. However, this can result in thermal stress and cracking of the wafers. Spin-on glass techniques do not produce the required adhesion for the passivation layer, unless high temperature curing processes are also used.

Alternative passivation materials that have a low CTE include polymeric materials with rigid-rod backbones. These polymeric materials can have CTEs closely matched to those of semiconductor materials, can be processed at low temperatures (when compared to dielectrics) and provide high adhesion to semiconductor surfaces. Examples of suitable polymeric passivation materials include the Polyimide PI-2611 (from HD Microsystems GmnbH) and Novastrat® 800 (from NeXolve Corporation).

A low stress passivation layer can have a CTE, for example, less than 10 ppm/° C., less than 8 ppm/° C., less than 6 ppm/° C., or less than 4 ppm/° C. A low stress passivation layer can have a CTE, for example, within a range from 1 ppm/° C. to 10 ppm/° C., from 2 ppm/° C. to 8 ppm/° C., or from 4 ppm/° C. to 6 ppm/° C. A low stress passivation layer can have a CTE that is matched to the average CTE of the semiconductors used in the device such as the average CTE of the heteroepitaxial layers and the substrate, for example, to within ±10%, ±20%, or ±40%. The CTE can represent a CTE over a temperature range, for example, from −200° C. to 150° C., from −150° C. to 100° C., or from −100° C. to 50° C. A low stress passivation layer can have a thickness, for example, from 1 μm to 40 μm, from 5 μm to 30 μm, or from 10 μm to 20 μm.

A low stress passivation layer can have a tensile strength, for example, from 200 MPa to 400 MPa such as from 250 MPa to 350 MPa. A low stress passivation layer can have a Young's modulus, for example, from 7 GPa to 10 GPa such as from 7.5 GPa to 9.5 GPa. A low stress passivation layer can have a tensile elongation, for example, from 80% to 120%, a such as from 90% to 110%. A low stress passivation layer can have a glass transition temperature, for example, from 300° C. to 450° C., such as from 300° C. to 400° C. A low stress passivation layer can have, for example, a coefficient of thermal conductivity from 5E-5 cal/cm×sec×° C. to 50 cal/cm×sec×° C.; a dielectric constant at 1 Hz and 50% RH from 2 to 4 such as from 2.5 to 3.5; a dissipation factor at 1 kHz from 0.0001 to 0.0003; a dielectric breakdown field greater than 1E6 V/cm; a volume resistivity greater than 10E16 Ωcm; and/or a surface resistivity greater than 1E15Ω. Tensile strength, Young's modulus, and tensile elongation can be determined according to ASTM D882-02 (at 23° C. and for a 0.7-mil thick layer). CTE can be determined using ASTM E831-06, for a 1-mil thick layer.

The passivation layer 913 can be applied using standard deposition techniques, for example spin coating. In some embodiments, hard baking can be used in a subsequent step. Photolithography and etching can then be used to pattern the passivation layer. In some embodiments, adhesion promoters can be used to enhance adhesion between the polyimide and the underlying layers. For PI-2611, the manufacturer recommends using aminosilane-based adhesion promoters such as VM-651 or VM-652 (from HD Microsystems GmbH). However, other suitable adhesion promoters are known and include, for example, to HMDS (hexamethyldisilazane), diphenylsilanediol-derivatives (AR 300-80), and cationic priming agents, for example SurPass®. In some embodiments, the thickness of the low stress passivation layer can be between 1 μm and 40 μm. In some embodiments, the thickness of the low stress passivation layer can be between 5 μm and 20 μm. In some embodiments, the thickness of the low stress passivation layer can be between 7.5 μm and 12.5 μm. In some embodiments, the low stress passivation layer may be formed using at least one spin-coating step.

In FIG. 10, TWV metal isolation resist pattern 1014 can be formed with a photosensitive polymer. This patterning can be carried out, for example, by photolithography techniques which may or may not require hard baking, depending on the specific embodiment. The bottom surface 1012 of the front surface contact 1001 remains exposed. FIG. 10 shows front surface contact 1001, patterned cap regions (post-cap etch) 1002A, ARC 1003, heteroepitaxial layer 1004, thinned substrate 1005, optically clear adhesive 1007, coverglass 1008, back surface 1009 of thinned substrate 1005, dual-depth TWV 1010, exposed bottom surface 1012 of the front surface contact 1001 after TWV etch stop removal, passivation layer 1013, and TWV metal isolation resist pattern 1014.

In FIG. 11, TWV metal 1115 is applied such that the TWV metal 1115 lines the previously exposed bottom of the front surface contact 1101, and lines the upper and lower sidewalls 1116A and 1116B of dual-depth TWV 1110, and lines the lower surface 1116C of the dual-level via, forming an electrical interconnection to the TWV front surface contact 1101. The TWV metal 1115 also lines a portion of the back side of the substrate (1117 and 1119), bounded by the resist 1114 from the previous step (FIG. 10). In some embodiments, these TWV and back side substrate metals (1115, 1116, 1117, and 1019) can be applied in a single deposition step. Sacrificial metal 1118 and metal isolation resist pattern 1114 can then be lifted off to isolate positive and negative electrical contacts (front side and back side electrical contacts), leading to the product shown in FIG. 12. FIG. 11 shows front surface contact 1101, patterned cap regions (post-cap etch) 1102A, ARC 1103, heteroepitaxial layer 1104, optically clear adhesive 1107, and coverglass 1108, overlying the wet etched back-thinned substrate 1105; dual-depth TWV 1110, passivation layer 1113, back side TWV metal isolation resist pattern 1114, TWV metal 1115 deposited on the bottom of the TWV interconnecting directly to the front surface contact 1101, TWV metal 1116A/1116B/1116C deposited along the sidewalls and lower surface of the TWV 1110 isolated from the heteroepitaxial layer 1104 and from the substrate 1105 by the passivation layer 1113, TWV metal 1117 deposited over a portion of passivation layer 1113, back side contact 1119 deposited on the back surface of thinned substrate 1105, and sacrificial metal 1118 on top of the isolation resist 1114.

The example of a completed dual-depth TWV structure shown in FIG. 12 includes front surface contact 1201, patterned cap regions (post-cap etch) 1202A, ARC 1203, residual ARC 1203A, heteroepitaxial layer 1204, thinned substrate 1205, optically clear adhesive 1207, coverglass 1208, dual-depth TWV 1210, dual-depth TWV metal 1215 deposited on the bottom of the TWV (electrically connecting directly to the top side metal pad 1201), TWV metal 1216 deposited along the sidewalls and lower surface of the dual-depth TWV 1210 and electrically isolated from the heteroepitaxial layer 1204 and from the thinned substrate 1205 by the passivation layer 1213, TWV metal 1217 deposited on a portion of the back side of the device, and back side contact 1219 electrically connected to substrate 1205.

A TWV can be, for example, from 10 μm to 50 μm deep, or from 10 μm to 200 μm deep, where depth is measured from the bottom of the front surface metal pad 1201 to the bottom surface of the TWV metal 1216 adjacent the TWV 1210. A TWV can have a width, for example, from about 10 μm to 500 μm, from 10 μm to 400 μm, from 100 μm to 400 μm, or from 100 μm to 250 μm, where width is measured from the interface between the heteroepitaxial layer 1204 and the passivation layer 1213 to the corresponding opposite interface. A TWV can be characterized, for example, by an aspect ratio from 0.5 to 1.5 from 0.8 to 1.2, or from 0.9 to 1.1, where the aspect ratio refers to the ratio of the depth to width.

The broad area via (or recess) can have a depth up to about 200 μm and lateral dimensions sufficiently large to accommodate insertion of a discrete bypass diode to be integrated in the recess. Bypass diodes may be square, rectangular, or triangular in shape, for example as described in https://solaerotech.com/solaerotech/wp-content/uploads/2018/04/SI-Bypass-Diode-Datasheet-April-2018.pdf, or as described in http://www.azurspace.com/images/pdfs/0002576-00-02_DB_SIA.pdf, and with thicknesses between about 120 μm and 160 μm. In many existing solar cells, triangular bypass diodes are usually welded to a corner of the front surface of a solar cell to minimize the solar cell surface area reduction. However, in the present invention, there is no shading of the front surface as the bypass diode can be placed on the back side of the solar cell. The bypass diode has a length, a width and an area. For example, the lateral dimensions of the bypass diodes may be up to about 10 mm by 18 mm, or up to 12 mm by 30 mm. In some embodiments, low-profile discrete diodes between about 75 μm and 130 μm thick and with a cross-sectional area of 14.4 mm² (3.8 mm on a side) can be used. In some embodiments, the broad area via can be square or rectangular in shape, with the broad area via dimensions providing at least 0.5 mm and up to 2 mm clearance between the bypass diode and the sides of the broad area via (or recess).

Referring to FIG. 12, depending on the width at the top of the TWV structure (at the bottom surface of the front surface metal pad 1201 between the patterned cap regions 1202A, there can be a residual ARC 1203A or section between a portion of the front side metal 1201 and the heteroepitaxial layer 1204. The residual ARC layer 1203A can overlie a portion of the heteroepitaxial layer between the patterned cap region 1202A and the passivation layer 1213 on the sidewall of the TWV. If the width of the top of the TWV is large, then there may not be a residual ARC layer in the top of the TWV within the patterned cap region.

After these processing steps, a bypass diode (BPD) 1336 can be integrated by placing in the recess formed by dual-depth TWV 1310. As shown in FIG. 13A, a space grade adhesive 1332 is deposited into dual-depth TWV, completely filling the lower portion of the TWV, and partially into the upper portion of the TWV, between about 1 μm and 25 μm above the height of the lower TWV. BPD 1336 is placed onto space grade adhesive 1332, which has a strong adhesion, and it is adhered to the structure. In an alternative embodiment show in in FIG. 13B, the lower via is filled with a low-CTE PI material 1334, such as that used for passivation layer 1313, which is then cured. In some embodiments, adhesion promoters can be used to enhance adhesion between the polyimide and the through-wafer-via structure. For PI-2611, the manufacturer recommends using aminosilane-based adhesion promoters such as VM-651 or VM-652 (from HD Microsystems GmbH). However, other suitable adhesion promoters are known and include, for example, to HMDS (hexamethyldisilazane), diphenylsilanediol-derivatives (AR 300-80), and cationic priming agents, for example SurPass®. The low-CTE PI material may be formed by multiple spin coating steps and may have a thickness suitable to planarize the lower TWV structure. A space grade adhesive 1332 is then deposited into the upper TWV (as shown), and BPD 1336 is placed onto space grade adhesive 1332, which has a strong adhesion, and is adhered to the structure.

Space grade adhesive 1332 must conform to ASTM E 595 specification limits and/or their NASA/ESA counterparts such as ESA PSS-014-072, with respect to outgassing rates and total mass loss. The adhesive must be able to function over an extended temperature range and should reliably compensate for the expansion properties of a variety of materials used to make the photovoltaic cell and panels. The adhesive should be able to dissipate stress that can arise due to large temperature variations experienced by satellites in operation. Space grade adhesive 1332 may be electrically conductive or electrically insulating. An example of a suitable material is Dow Corning® 93-500 space grade encapsulant. An example of an electrically conductive adhesive is EPO-TEK® E2101. Other low-outgassing adhesive materials exist and fulfil the ASTM E 595 specification criteria.

FIG. 14 shows an embodiment where a coplanar bypass diode 1436 is mounted in the broad area via or recess and is adhered using a non-conductive space grade adhesive 1434, that extends up to approximately 1 μm to 25 μm above the height of the TWV and into the broad area via or recess. Bypass diode 1436 has a first contact pad 1438 and a second contact pad 1440. One of the contact pads is formed on p-type material of BPD 1436, and the other contact pad is formed on n-type material of BPD 1436. To function as a BPD, the p-type contact pad of the BPD is connected to the n-contact metal of the dual-depth TWV structure, and the n-type contact pad of the BPD is connected to the p-contact metal of the dual-depth TWV, providing a parallel path for current. As shown, contact 1438 of BPD 1436 is electrically connected to back metal contact 1419 via metal interconnection 1442, and contact 1440 of BPD 1436 is connected to TWV metal 1417 via metal interconnection 1444. TWV metal 1417 is interconnected to metal 1415 and front contact 1401. Metal interconnections 1442 and 1444 can be formed by wire bonding, or via welding steps.

FIG. 15 shows an embodiment where a stacked junction bypass diode 1536 is mounted in the broad area via or recess and is adhered using a conductive space grade adhesive 1534 that extends up to approximately 1 μm to 25 μm above the height of the TWV and into the broad area via or recess. The bypass diode comprises a region with first conductivity type 1537 and a region with second conductivity type 1539, which may be metallized. In this embodiment, the first conductivity region 1537 is wire bonded or welded by electrical interconnect 1542 to back metal contact 1519 and the second conductivity region is electrically connected to TWV metal 1517 by conductive space grade adhesive 1534. TWB metal 1517 is interconnected to via metal 1515 and front contact 1501. This configuration requires one less wire bond or weld that the example shown in FIG. 14.

In one embodiment, the bypass diode is a stacked junction device with a thickness of 150 μm, a maximum length of approximately 17.8 mm and a maximum width of approximately 9.6 mm, with a triangular shape.

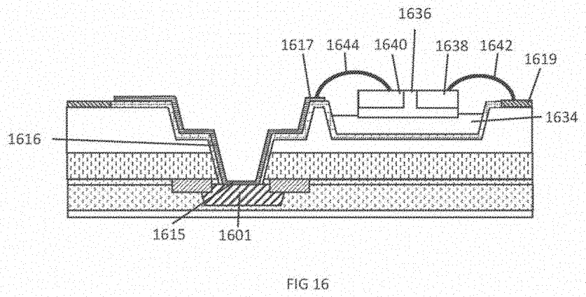

FIG. 16 shows another embodiment where a coplanar bypass diode 1636 is mounted in a second broad area via or recess and is adhered using a non-conductive space grade adhesive 1634, that is between 2 μm and 10 μm thick. The second broad area via or recess can have a different size from the dual-depth via used to make electrical connection with front surface contact 1601. Bypass diode 1636 has a first contact pad 1638 and a second contact pad 1640. One of the contact pads is formed on p-type material of BPD 1636, and the other contact pad is formed on n-type material of BPD 1636. To function as a BPD, the p-type contact pad of the BPD is connected to the p-contact metal of the dual-depth TWV structure, and the n-type contact pad of the BPD is connected to the n-contact metal of the dual-depth TWV, providing a parallel path for current. As shown, contact 1638 of BPD 1636 is electrically connected to back metal 1619 via metal interconnection 1642, and contact 1640 of BPD 1636 is connected to TWV metal 1617 via metal interconnection 1644. TWV metal 1617 is interconnected to TWV metal 1615, which is interconnected to front surface metal 1601. Metal interconnections 1642 and 1644 can be formed by wire bonding, or via welding steps.

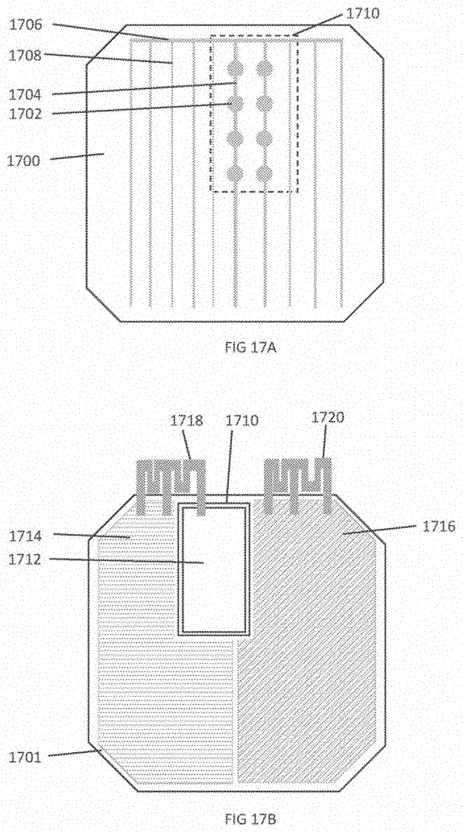

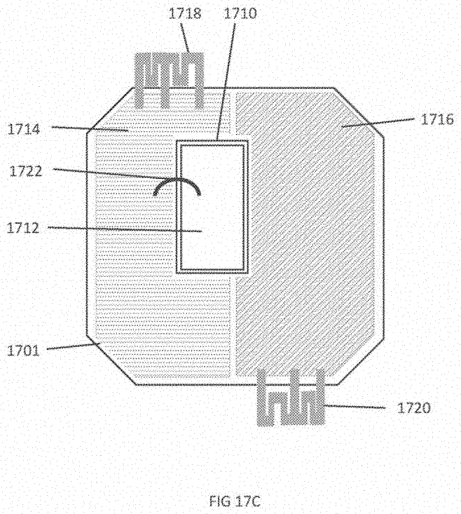

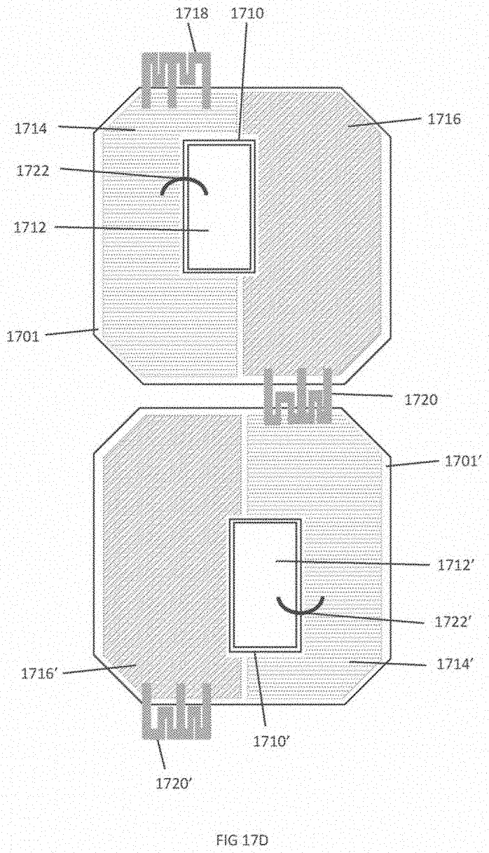

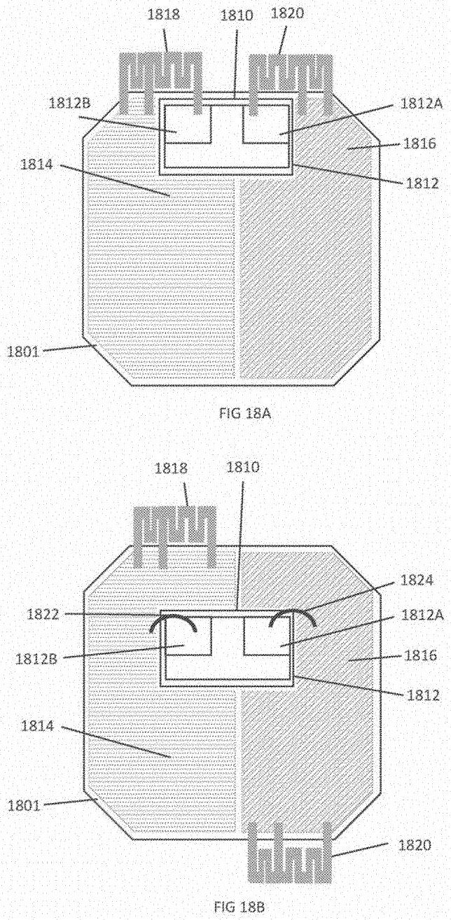

FIGS. 17A and 17B show front and backside views, respectively, of the solar cell shown in FIG. 15. FIG. 17A shows front surface 1700 having a number of metal caps 1702, formed within dual-depth through-wafer-via 1710 on the backside of the cell. The cell has at least one cap and one TWV making connection to the back side of the wafer. Additional TWVs and caps can improve electrical performance of the cell. The caps 1702 are connected on the front side to electrical gridlines 1704 connected to horizontal gridline 1706. Additional gridlines 1708 extend horizontally from gridline 1706. Metal caps 1702 can be between 100 μm and 500 μm wide. Metal gridlines 1704 and 1706 can be between 25 μm and 50 μm wide. Metal gridlines 1708 can be between 10 μm and 20 μm wide. The sum of the area of metal caps 1702, and metal gridlines 1704, 1706 and 1708 is less than the area of the gridlines, metal cap, busbar and bypass diode on a conventional solar cell. FIG. 17B shows back surface 1701, and through wafer-via 1710. Stacked planar diode 1712 is placed within the recess provided by through-wafer-via 1710. The bottom side of bypass diode 1712 is electrically connected to contact metal 1716. The topside contact of bypass diode 1712 is electrically connected to contact metal 1714, through welded contact 1718. Welded contact 1720 is applied to contact metal 1716. Contacts 1718 and 1720 allow additional cells to be stringed together.

FIG. 17C shows a backside view of another solar cell as shown in FIG. 15. FIG. 17B shows back surface 1701, and through wafer-via 1710. Stacked planar diode 1712 is placed within the recess provided by through-wafer-via 1710. The bottom side of bypass diode 1712 is electrically connected to contact metal 1716. The topside contact of bypass diode 1712 is electrically connected to contact metal 1714, through interconnect 1722, which can be a wire bond. Welded contact 1718 is applied to metal 1714 and welded contact 1720 is applied to contact metal 1716. Contacts 1718 and 1720 allow additional cells to be strung together, as shown in FIG. 17D.

FIG. 18A shows the backside view of a solar cell according to the embodiment shown in FIG. 14, with backside surface 1801, through wafer-via 1810, contact metal 1814, contact metal 1816, and with a coplanar bypass diode 1812. Electrical contact 1812A of bypass diode 1812 is electrically connected to contact metal 1816 through welded contact 1820. Electrical contact 1812B of bypass diode 1812 is electrically connected to contact metal 1814, through welded contact 1818. Contacts 1818 and 1820 allow additional cells to be stringed together.

FIG. 18B shows the backside view of another solar cell according to the embodiment shown in FIG. 14, with backside surface 1801, through wafer-via 1810, contact metal 1814, contact metal 1816, and with a coplanar bypass diode 1812. Electrical contact 1812A of bypass diode 1812 is electrically connected to contact metal 1816 through interconnect 1824, which can be a wire bond. Electrical contact 1812B of bypass diode 1812 is electrically connected to contact metal 1814 through interconnect 1822, which can be a wire bond. Welded contact 1818 is connected to contact metal 1814 and welded contact 1820 is connected to metal contact 1816. Welded contacts 1818 and 1820 allow additional cells to be stringed together.

In several of these examples, the dual-depth via is shown as being offset from the center and towards an edge of the solar cell. In some embodiments, the dual-depth through wafer-via is placed such that an edge of the dual-depth through wafer-via is within 2 mm of the closest edge of the cell, or within 1 mm of the edge of the cell, or within 0.5 mm of the edge of the cell. Placement of the via in this manner, along with associated metallization for the two contacts can facilitate welding or wire bonding of the cell for some embodiments and can reduce the number of such connections. In other embodiments, the dual-depth via is placed such that the closest edged of the dual-depth via is more than 2 mm from the edge of the closest cell edge. A bypass diode placed within such a dual-depth via can be electrically connected to the contact metal via interconnects (as shown in FIG. 18B), and the welding for welded contacts takes place only on the contact metal regions (1814, 1816).

In some embodiments, welding for the welded contacts can be formed at a distance between 150 μm and 750 μm from the edge of the cell, or between 300 μm and 500 μm from the edge of the cell. On the front side of the cell (not shown) at least one metal cap is formed within the broad area via, and electrical connections are made as shown in FIG. 17A.

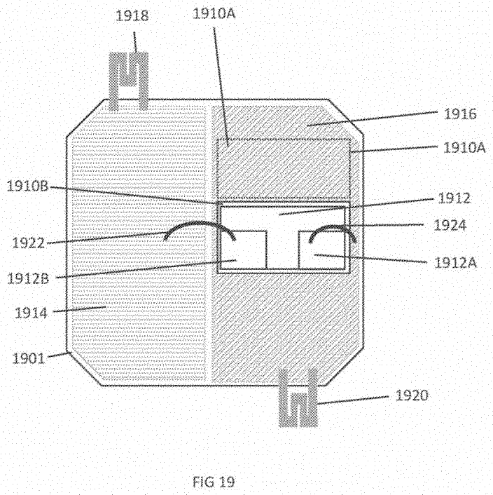

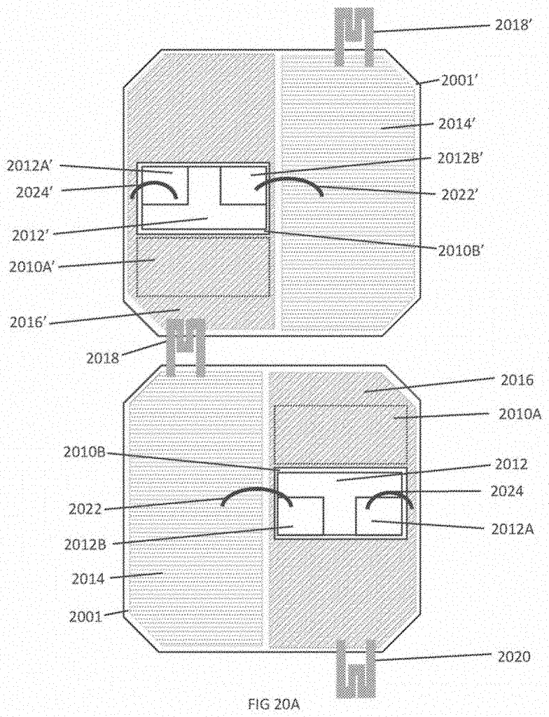

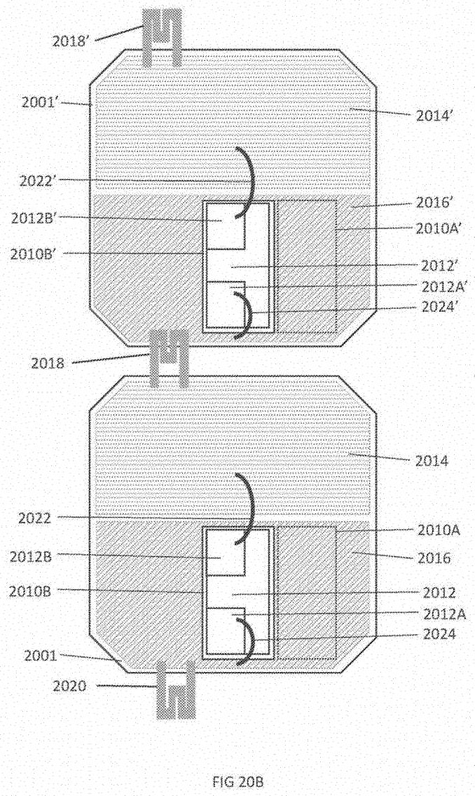

FIG. 19 shows the backside view of a solar cell according to the embodiment shown in FIG. 16, with backside surface 1901, through wafer-via 1910A, shallow recess 1910B, contact metal 1914, contact metal 1916, and with a coplanar bypass diode 1912. Electrical contact 1912A of bypass diode 1912 is electrically connected to contact metal 1916 through interconnect 1924, which can be a wire bond. Electrical contact 1912B of bypass diode 1912 is electrically connected to contact metal 1914, interconnect 1922, which can be a wire bond. Welded contact 1918 is connected to metal 1914 and welded contact 1920 is connected to metal 1916. Welded contacts 1918 and 1920 allow additional cells to be stringed together. In some embodiments, welding can be formed at a distance between 150 μm and 750 μm from the edge of the cell, or between 300 μm and 500 μm from the edge of the cell. On the front side of the cell (not shown) at least one metal cap is formed within the broad area via 1910A, and electrical connections are made as shown in FIG. 17A.

FIGS. 20A and 20B show the backside view of two interconnected solar cells according to the embodiment shown in FIG. 16 and FIG. 19. The first solar cell has features as shown, formed on the backside surface 2001. The second solar cell has features as shown, formed on the backside surface 2001′. Welded contact 2018 is connected with metal 2014 of the first solar cell and metal 2016′ of the second solar cell. Welded contact 2020 is connected with metal 2016 of the first solar cell and metal 2014′ of the second solar cell. Contact metals 2014 and 2016 for the first cell, and contact metals 2014′ and 2016′ for the second cell are defined through lithography to ensure that when cells are placed adjacent to each other as shown, a proper series connection can be made between the p-contact of one cell and the n-contact of an adjacent cell, or the n-contact of one cell and the p-contact of another adjacent cell. Welded contact 2018′ connected with metal 2016′ of the second solar cell, and welded contact 2020′ connected with metal 2014′ of the second solar cell can be connected to a further solar cell. FIGS. 20A and 20B include backside surface 2001/2001′, through wafer via 2010A/2010A′, shallow recess 2010B/2010B′, bypass diode 2012/2012′, electrical contact 2012A/2012A′, electrical contact 2012B/2012B′, contact metal 2014/2014′, contact metal 2016/2016′, welded contacts 2018/2018′/2020; interconnect 2022/2022′, and interconnect 2024/2024′.

The dual-depth via structure with an embedded BPD represents advantageous improvement over prior art, resulting in improved fabrication reliability and yield of devices that comprise a heteroepitaxial layer. Bonding the coverglass to the front surface of the device before fabrication of the dual-depth TWV provides a carrier for subsequent processing. Importantly the thick substrate used during epitaxial growth can be thinned using one or more methods to provide a thin substrate. The substrate facilitates the formation of high quality dual-depth TWVs using wet etching, can reduce shadowing of the front surface by a bypass diode and can simplify the wire bonding or welding step to just one side of the cell, with improved yield and reliability as the welds are formed on a device with a carrier. Embedding the bypass diode within the dual-depth via using a space grade adhesive can also provide an improved mechanical strength for the thinnest parts of the device structure.

Methods of forming a semiconductor device can comprise the steps of: providing a semiconductor wafer, wherein the semiconductor wafer comprises: a substrate region comprising a front side and a back side; a heteroepitaxial layer overlying the front side of the substrate region, wherein, the heteroepitaxial layer comprises a first subcell and at least one additional subcell overlying the first subcell; and at least one of the first subcell or the at least one additional subcell comprises an alloy comprising one or more elements from group III of the periodic table, N, As, and an element selected from Sb, Bi and a combination thereof; a plurality of patterned cap regions overlying the heteroepitaxial layer; an anti-reflective coating overlying the heteroepitaxial layer; and a corresponding metal region overlying each of the plurality of patterned cap regions; bonding a coverglass to the front side of the semiconductor wafer with an optically clear adhesive; optionally removing a desired amount from the semiconductor wafer by a thinning of the substrate region from the back side of the semiconductor wafer; patterning the backside of the semiconductor wafer with a back etch broad area via or recess pattern; etching from the backside of the semiconductor wafer a broad area via or recess within the substrate layer using a peroxide based wet etch; patterning the back side of the semiconductor wafer with a back etch through-wafer-via pattern within the broad area via or recess; etching from the back side of the semiconductor wafer a plurality of through-wafer-vias using a single wet etchant mixture, wherein each of the plurality of through-wafer-vias extends from the back side of the semiconductor wafer to the anti-reflective coating overlying the heteroepitaxial layer; removing the anti-reflective coating to expose a bottom side of the corresponding metal region with a subsequent wet etching method, wherein the subsequent wet etching method is specific for the removal of the anti-reflective coating; depositing a passivation layer on the through-wafer-via walls with standard deposition techniques; depositing a resist pattern on the back side of the semiconductor wafer for back side metal isolation, wherein the resist pattern underlies the passivation layer; depositing a metal on the back side of the semiconductor wafer and on the through-wafer-via; removing the resist pattern and a sacrificial metal; depositing a space grade adhesive within the dual-depth through-wafer-via; and adhering a bypass diode within the broad area via or recess using the space grade adhesive.

Semiconductor devices can comprise a heteroepitaxial layer, further comprising an alloy comprising one or more elements from group III of the periodic table, N, As, and an element selected from Sb, Bi and a combination thereof; and a dual-depth through-wafer-via characterized by the absence of pitting on smooth sidewall surfaces formed by a method provided by the present disclosure.

Dual-depth through-wafer-via structures can comprise a substrate comprising a back side and a front side; a heteroepitaxial layer overlying the front side of the substrate; an antireflection coating overlying a first portion of the heteroepitaxial layer; a patterned cap region overlying a second portion of the heteroepitaxial layer; a front surface contact overlying and electrically connected to the patterned cap region, wherein the front surface contact comprises a bottom surface; and a dual-depth through-wafer-via with a broad area via or recess and a through-wafer-via extending from the lower surface of the broad area via to the front surface contact, wherein the dual-depth through-wafer-via comprises a sidewall; a low stress passivation layer overlying a portion of the back side of the substrate and the sidewall of the through-wafer-via; and a metal layer overlying the low stress passivation layer and the bottom surface of the front surface contact within the dual-depth through-wafer-via.

Devices provided by the present disclosure facilitate lower-cost, lower-complexity, higher-speed fabrication of solar arrays with low mass and high reliability. This is accomplished by eliminating the front side welding process, reducing the thickness and cost of the backside metal, reducing the overall mass of the photovoltaic device by using a thin substrate, integrating the coverglass during wafer processing, increasing solar array area utilization with the interconnections and bypass diodes integrated with interconnection substrates such as PWBs/PCBs, and increasing wafer utilization with small cells.

### Aspects of the Invention

Aspect 1. A dual-depth through-wafer-via structure, comprising: a substrate having a front substrate surface and a back substrate surface, wherein the substrate has a thickness from 20 μm to 200 μm; a plurality of heteroepitaxial layers overlying the front substrate surface; a front surface contact overlying a portion of and electrically connected to the plurality of heteroepitaxial layers; an optical adhesive overlying the front surface contact and the plurality of heteroepitaxial layers; a coverglass overlying the optical adhesive; a back surface contact pad underlying a portion of and electrically connected to the back substrate surface; a front surface contact pad underlying and insulated from the back substrate surface; and a dual-depth through-wafer-via interconnecting the front surface contact pad and the front surface contact, wherein the dual-depth through-wafer-via comprises: a sidewall and a low stress passivation layer lining the sidewall; and a through-wafer-via metal overlying the passivation layer.

Aspect 2. The dual-depth through-wafer-via structure of aspect 1, wherein the low stress passivation layer comprises a polyimide.

Aspect 3. The dual-depth through-wafer-via structure of any one of aspects 1 to 2, wherein the low stress passivation layer has a coefficient of thermal expansion from 1 ppm/° C. to 10 ppm/° C., over a temperature range from −100° C. to 50° C.

Aspect 4. The dual-depth through-wafer-via structure of any one of aspects 1 to 3, wherein the low stress passivation layer has a thermal expansion coefficient that matches an average thermal expansion coefficient of the substrate and of the plurality of heteroepitaxial layers within ±40%.

Aspect 5. The dual-depth through-wafer-via structure of any one of aspects 1 to 4, wherein the low stress passivation layer has a thickness from 1 μm to 40 μm.

Aspect 6. The dual-depth through-wafer-via structure of any one of aspects 1 to 5, wherein the sidewall is smooth.

Aspect 7. The dual-depth through-wafer-via structure of any one of aspects 1 to 6, wherein the back substrate surface is free from pitting.

Aspect 8. The dual-depth through wafer-via structure of any one of aspects 1 to 7, further comprising a bypass diode placed within the broad-area via either flush with the back substrate surface, or slightly protruding from the back substrate surface, and connected electrically to the dual-depth through-wafer-via structure.

Aspect 9. The dual-depth through-wafer-via structure of any one of aspects 1 to 8, wherein the dual-depth through-wafer-via comprises: a first via extending from the back substrate surface to the front surface contact pad; and a second broad area via extending from the back substrate surface to a depth with in the substrate, wherein the first via has a width that is less than the width of the second truncated via.

Aspect 10. The dual-depth through-wafer-via structure of aspect 9, wherein the broad area via comprises a bypass diode.

Aspect 11. The dual-depth through-wafer-via structure of aspect 10, wherein the bypass diode is electrically interconnected to the through-wafer-via metal and to a back surface contact pad.

Aspect 12. The dual-depth through-wafer-via structure of aspect 9, wherein the broad area via comprises: an adhesive overlying the through-wafer-via metal; and a bypass diode mounted on the adhesive.

Aspect 13. The dual-depth through-wafer-via structure of aspect 12, wherein the adhesive comprises an electrically conductive adhesive.

Aspect 14. The dual-depth through-wafer-via structure of aspect 13, wherein the electrically conductive adhesive interconnects the bypass diode to the through-wafer-via metal.

Aspect 15. The dual-depth through-wafer-via structure of aspect 10, wherein the bypass diode is welded or wire bonded to the through-wafer-via metal, to the back surface contact, or to both the through-wafer-via metal and to the back surface contact.

Aspect 16. The dual-depth through-wafer-via structure of any one of aspects 1 to 15, comprising a broad area recess in the back surface of the substrate.

Aspect 17. The dual-depth through-wafer-via structure of aspect 16, wherein the broad area recess comprises an adhesive and a bypass diode mounted to the adhesive.

Aspect 18. The dual-depth through-wafer-via structure of aspect 17, wherein the adhesive comprises an electrically conductive adhesive.

Aspect 19. The dual-depth through-wafer-via structure of aspect 18, wherein the electrically conductive adhesive interconnects the bypass diode to the through-wafer-via metal.

Aspect 20. The dual-depth through-wafer-via structure of aspect 17, wherein the bypass diode is welded or wire bonded to the through-wafer-via metal, to the back surface contact, or to both the through-wafer-via metal and to the back surface contact.

Aspect 21. A semiconductor device comprising the dual-depth through-wafer-via structure of any one of aspects 1 to 20.

Aspect 22. A multijunction photovoltaic cell comprising the dual-depth through-wafer-via structure of any one of aspects 1 to 20.

Aspect 23. A photovoltaic module comprising a plurality of the multijunction photovoltaic cells of aspect 22.

Aspect 24. A method of fabricating a through-wafer-via structure, comprising:

(a) providing a semiconductor wafer, wherein the semiconductor wafer comprises: a substrate comprising a front substrate surface and a back substrate surface; a plurality of heteroepitaxial layers overlying the front substrate surface; a front surface contact overlying and electrically connected to a portion of the plurality of heteroepitaxial layers; an optical adhesive overlying the front surface contact and the plurality of heteroepitaxial layers; and a coverglass overlying the optical adhesive layer;

(b) forming a broad area via structure within the back substrate surface;

(c) forming a through-wafer-via within the broad area via structure and interconnecting the front surface contact, wherein the through-wafer-via comprises a sidewall and a low-stress passivation layer lining the sidewall, and a through-wafer-via metal overlying the passivation layer; and

(d) forming a front contact pad interconnecting the through-wafer-via and the front surface contact.

Aspect 25. The method of aspect 24, further comprising, before forming the broad area via structure, thinning the substrate to a thickness from 75 μm to 150 μm.

Aspect 26. The method of any one of aspects 24 to 25, further comprising, after forming the front contact pad, mounting a bypass diode in the broad area via.

Aspect 27. The method of aspect 26, further comprising interconnecting the bypass diode to the through wafer via metal and to a back surface contact pad.

Aspect 28. The method of any one of aspects 24 to 27, wherein the low-stress passivation layer comprises a polyimide.

Aspect 29. The method of any one of aspects 24 to 28, wherein the low-stress passivation layer has a coefficient of thermal expansion from 1 ppm/° C. to 10 ppm/° C., over a temperature range from −100° C. to 50° C.

Aspect 30. The method of any one of aspects 24 to 29, wherein the low-stress passivation layer has a thermal expansion coefficient that matches an average thermal expansion coefficient of the substrate and of the plurality of heteroepitaxial layers within ±40%.

Aspect 31. The method of any one of aspects 24 to 30, wherein the low-stress passivation layer has a thickness from 1 μm to 40 μm.

Aspect 32. The method of any one of aspects 24 to 31, wherein the sidewall is smooth.

Aspect 33. The method of any one of aspects 24 to 32, wherein the back substrate surface is free from pitting.

Aspect 34. A semiconductor device comprising a dual-depth through-wafer-via structure fabricated by the method of any one of aspects 24 to 34.

Aspect 35. A multijunction photovoltaic cell comprising a dual-depth through-wafer-via structure fabricated by the method of any one of aspects 24 to 34.

Aspect 36. A photovoltaic module comprising a plurality of the multijunction photovoltaic cells of aspect 35.

Finally, it should be noted that there are alternative ways of implementing the embodiments disclosed herein. Accordingly, the present embodiments are to be considered as illustrative and not restrictive. Furthermore, the claims are not to be limited to the details given herein and are entitled their full scope and equivalents thereof.

1. A dual-depth through-wafer-via structure, comprising:
a substrate having a front substrate surface and a back substrate surface, wherein the substrate has a thickness from 20 μm to 200 μm;
a plurality of heteroepitaxial layers overlying the front substrate surface;
a front surface contact overlying a portion of and electrically connected to the plurality of heteroepitaxial layers;
an optical adhesive overlying the front surface contact and the plurality of heteroepitaxial layers;
a coverglass overlying the optical adhesive;
a back surface contact pad underlying a portion of and electrically connected to the back substrate surface;
a front surface contact pad underlying and insulated from the back substrate surface; and
a dual-depth through-wafer-via interconnecting the front surface contact pad and the front surface contact, wherein the dual-depth through-wafer-via comprises:
a sidewall;
a passivation layer lining the sidewall, and
a through-wafer-via metal overlying the passivation layer.

2. The dual-depth through-wafer-via structure of claim 1, wherein the passivation layer comprises a polyimide.

3. The dual-depth through-wafer-via structure of claim 1, wherein the passivation layer has a coefficient of thermal expansion from 1 ppm/° C. to 10 ppm/° C., over a temperature range from −100° C. to 50° C.

4. The dual-depth through-wafer-via structure of claim 1, wherein the passivation layer has a thermal expansion coefficient that matches an average thermal expansion coefficient of the substrate and of the plurality of heteroepitaxial layers within ±40%.

5. The dual-depth through-wafer-via structure of claim 1, wherein the passivation layer has a thickness from 1 μm to 40 μm.

6.-7. (canceled)

8. The dual-depth through wafer-via structure of claim 1, further comprising:
a bypass diode, wherein the bypass diode is either flush with the back substrate surface or slightly protruding from the back substrate surface, wherein the bypass diode is connected electrically to the dual-depth through-wafer-via.

9. The dual-depth through-wafer-via structure of claim 1, wherein the dual-depth through-wafer-via comprises:
a first via extending from the back substrate surface to the front surface contact pad; and
a second via extending from the back substrate surface to a depth within the substrate,
wherein the first via has a width that is less than a width of the second via.

10. The dual-depth through-wafer-via structure of claim 9, wherein the second via comprises:
an electrically conductive adhesive overlying the dual-depth through-wafer-via metal; and
a bypass diode mounted on the adhesive.

11.-13. (canceled)

14. The dual-depth through-wafer-via structure of claim 10, wherein the electrically conductive adhesive interconnects the bypass diode to the dual-depth through-wafer-via metal.

15. The dual-depth through-wafer-via structure of claim 1, further comprising:
a bypass diode, wherein the bypass diode is welded or wire bonded to the dual-depth through-wafer-via metal, to the back surface contact pad, or to both the dual-depth through-wafer-via metal and to the back surface contact pad.

16.-19. (canceled)

20. The dual-depth through-wafer-via structure of claim 1, further comprising:
a bypass diode, wherein the bypass diode is electrically interconnected to the dual-depth through-wafer-via metal and to the back surface contact pad.

21. A semiconductor device comprising the dual-depth through-wafer-via structure of claim 1.

22. A multijunction photovoltaic cell comprising the dual-depth through-wafer-via structure of claim 1.

23. A photovoltaic module comprising a plurality of the multijunction photovoltaic cells of claim 22.

24. A method of fabricating a through-wafer-via structure, comprising:
(a) providing a semiconductor wafer, wherein the semiconductor wafer comprises:
a substrate comprising a front substrate surface and a back substrate surface,
a plurality of heteroepitaxial layers overlying the front substrate surface,
a front surface contact overlying and electrically connected to a portion of the plurality of heteroepitaxial layers,
an optical adhesive overlying the front surface contact and the plurality of heteroepitaxial layers, and
a coverglass overlying the optical adhesive layer;
(b) forming via structure within the back substrate surface;
(c) forming a through-wafer-via within the via structure and interconnecting the front surface contact, wherein the through-wafer-via comprises:
a sidewall
a passivation layer lining the sidewall, and
a through-wafer-via metal overlying the passivation layer; and
(d) forming a front contact pad interconnecting the through-wafer-via and the front surface contact.

25. The method of claim 24, further comprising:
before forming the via structure, thinning the substrate to a thickness from 20 μm to 200 μm.

26. The method of claim 24, further comprising:
after forming the front contact pad, mounting a bypass diode in the via structure.

27. The method of claim 26, further comprising:
interconnecting the bypass diode to the through-wafer-via metal and to a back surface contact pad.

28. -30. (canceled)

31. The method of claim 24, wherein the passivation layer has a thickness from 1 μm to 40 μm.

32. The method of claim 24, wherein the sidewall is smooth.

33. The method of claim 24, wherein the back substrate surface is free from pitting.

34.-36. (canceled)
